(19) United States
(12) Patent Application Publication
(10) Pub. No.: US 2019/0246484 A1
(43) Pub. Date: Aug. 8, 2019

(54) PLASMA SIMULATION WITH NON-LINEAR OPTICS

(71) Applicant: Raytheon BBN Technologies Corp., Cambridge, MA (US)

(72) Inventor: Hari Kiran Krovi, Lexington, MA (US)

(21) Appl. No.: 15/887,040

(22) Filed: Feb. 2, 2018

(51) Int. Cl. H05H 1/46; H01J 37/32; H01L 51/42; G01T 1/29

(52) U.S. Cl. CPC H05H 1/46; H01J 37/32972; G01T 1/2914; H01L 51/42; H01J 37/32339

(57) ABSTRACT

An optical system for modeling a distribution of plasma particles is provided. The system includes an electromagnetic wave generator configured to generate an electromagnetic wave having a first set of values of a parameter, a non-linear medium configured to receive, from the electromagnetic wave generator, the electromagnetic wave, an output detector configured to detect a second set of values of the parameter responsive to propagation of the electromagnetic wave through the non-linear medium, and a controller configured to select the first set of values of the parameter, communicate the first set of values of the parameter to the electromagnetic wave generator, receive, from the output detector, the second set of values of the parameter, and determine, based on the first set of values of the parameter and the second set of values of the parameter, a distribution of plasma particles.

### GOVERNMENT INTEREST STATEMENT

This invention was made with government support under Contract Number HR0011-17-C-0022 awarded by the Defense Advanced Research Projects Agency Defense Sciences Office (DARPA DSO). The government has certain rights in the invention.

### BACKGROUND

Plasma is a highly-conductive state of matter resembling an ionized gas. Plasma includes positive ions, which are relatively heavy, and free electrons, which are relatively light and which have become unbound from the positive ions. Although the positive ions remain relatively static, the free electrons move about the plasma freely in response to magnetic and electric fields applied to the plasma. Plasmas are of significant interest at least because, unlike other states of matter, the movement and distribution of plasma particles is dominated by the effects of magnetic and electric fields.

### SUMMARY OF THE INVENTION

Aspects and embodiments are generally directed to an optical system for modeling a distribution of plasma particles. The system includes an electromagnetic wave generator configured to generate an electromagnetic wave having a first set of values of at least one parameter, a non-linear medium configured to receive, from the electromagnetic wave generator, the electromagnetic wave, an output detector configured to detect a second set of values of the at least one parameter responsive to propagation of the electromagnetic wave through the non-linear medium, and a controller configured to select the first set of values of the at least one parameter, communicate the first set of values of the at least one parameter to the electromagnetic wave generator, receive, from the output detector, the second set of values of the at least one parameter, and determine, based on the first set of values of the at least one parameter and the second set of values of the at least one parameter, a distribution of plasma particles.

In at least one embodiment, the at least one parameter includes at least one of a phase of the electromagnetic wave and an amplitude of the electromagnetic wave. In some embodiments, the at least one parameter is indicative of a speckle distribution function of the electromagnetic wave. In one embodiment, the non-linear medium has a negative group velocity distribution coefficient. In an embodiment, the controller is further configured to modulate a value of the negative group velocity distribution coefficient of the non-linear medium.

In some embodiments, the non-linear medium includes a pair of diffraction gratings. In at least one embodiment, the non-linear medium includes a pair of prisms. In one embodiment, the non-linear medium includes at least one graded-index lens. In at least one embodiment, the non-linear medium includes one or more metamaterials. In some embodiments, the system includes a pump beam generator configured to provide a pump beam to the non-linear medium.

In at least one embodiment, providing the pump beam to the medium modifies the electron structure of the non-linear medium. In an embodiment, the output detector includes a volume hologram. In one embodiment, the output detector is configured to detect the second set of values of the at least one parameter using linear tomography.

According to at least one aspect of the invention, a method of modeling a distribution of plasma particles is provided. The method includes acts of selecting a first set of values of one or more parameters of an electromagnetic wave, communicating the one or more parameters to an electromagnetic wave generator, detecting a second set of values for the one or more parameters of the electromagnetic wave, analyzing the first set of values of the one or more parameters and the second set of values of the one or more parameters, and determining, based on the analysis, a distribution of particles in a plasma system.

In one embodiment, the one or more parameters include at least one of a phase of the electromagnetic wave and an amplitude of the electromagnetic wave. In at least one embodiment, the one or more parameters are indicative of a speckle distribution function of the electromagnetic wave. In some embodiments, the method further includes an act of modulating a group velocity distribution coefficient of a medium interacting with the electromagnetic wave.

According to some aspects of the invention, a non-transitory computer-readable medium storing sequences of computer-executable instructions for modeling a distribution of plasma particles is provided. The sequences of computer-executable instructions include instructions that instruct at least one processor to select a first set of values of one or more parameters of an electromagnetic wave, communicate the one or more parameters to an electromagnetic wave generator, detect a second set of values for the one or more parameters of the electromagnetic wave, analyze the first set of values of the one or more parameters and the second set of values of the one or more parameters, and determine, based on the analysis, a distribution of particles in a plasma system.

In some embodiments, the one or more parameters include at least one of a phase of the electromagnetic wave and an amplitude of the electromagnetic wave. In at least one embodiment, the sequences of computer-executable instructions further include instructions that instruct the at least one processor to modulate a group velocity distribution coefficient of a medium interacting with the electromagnetic wave.

Still other aspects, embodiments, and advantages of these exemplary aspects and embodiments are discussed in detail below. Embodiments disclosed herein may be combined with other embodiments in any manner consistent with at least one of the principles disclosed herein, and references to “an embodiment,” “some embodiments,” “an alternate embodiment,” “various embodiments,” “one embodiment” or the like are not necessarily mutually exclusive and are intended to indicate that a particular feature, structure, or characteristic described may be included in at least one embodiment. The appearances of such terms herein are not necessarily all referring to the same embodiment. Various aspects and embodiments described herein may include means for performing any of the described methods or functions.

### BRIEF DESCRIPTION OF THE DRAWINGS

Various aspects of at least one embodiment are discussed below with reference to the accompanying figures, which are not intended to be drawn to scale. The figures are included to provide an illustration and a further understanding of the various aspects and embodiments, and are incorporated in and constitute a part of this specification, but are not intended as a definition of the limits of any particular embodiment. The drawings, together with the remainder of the specification, serve to explain principles and operations of the described and claimed aspects and embodiments. In the figures, each identical or nearly identical component that is illustrated in various figures is represented by a like numeral. For purposes of clarity, not every component may be labeled in every figure. In the figures:

FIG. 1 is a graph illustrating a distribution function in a plasma system;

FIG. 2 is a graph illustrating a distribution function in an optical system;

FIG. 3 is a block diagram of an example of an optical system according to one embodiment; and

FIG. 4 is a flow diagram illustrating a method of determining a distribution of plasma particles according to one embodiment.

### DETAILED DESCRIPTION

As discussed above, plasma consists of positive ions and free electrons, where the movement of the free electrons is dominated by the effects of electric and magnetic fields. An initial distribution of positive ions and free electrons within a plasma, measured at an arbitrary “start” time, is subject to change in response to the effects of electric and magnetic fields. If the initial distribution of positive ions and free electrons within the plasma is known, conventional calculations may be executed to determine a distribution of the positive ions and the free electrons in the plasma at a subsequent point in time.

The calculation of a plasma particle distribution offers significant insight into wave-particle interactions. However, directly calculating the distribution of positive ions and free electrons in a plasma is extremely computationally-intensive. For example, executing the calculation may require hundreds of thousands of processors executing in a clustered architecture, and may consume several megawatts of power. Accordingly, it would be advantageous to be able to reduce the computational complexity of determining a plasma particle distribution.

Aspects and embodiments are directed to a non-linear optical model of plasma dynamics. The non-linear optical model includes a medium, and a laser beam that is directed through the medium. The medium is a non-linear optical medium, such as a non-linear crystal material, for example. As discussed in greater detail below, the laser beam interacts with medium in a manner similar to the interaction of an electromagnetic wave with a plasma. Accordingly, the optical model may be used to simulate the effect of an electromagnetic wave on a plasma. Where the initial distribution of the plasma and properties of the electromagnetic wave are known, the optical model may be used to determine a particle distribution in the plasma subsequent to the electromagnetic wave being applied to the plasma.

More specifically, the phase and amplitude of a laser beam encode information indicative of a particle distribution in the plasma. In one example, the phase and amplitude of the incident laser beam encode an initial distribution of particles within the plasma. As the laser beam passes through the non-linear optical medium, the beam interacts with the medium in a manner analogized to the manner in which an electric field interacts with plasma particles. The emergent laser beam is measured to determine a change in phase and amplitude, which is analyzed to determine an analogous change in plasma particle distribution. In some examples, the emergent laser beam is indicative of an electron distribution in plasma, whereas the ion distribution in the plasma is assumed to be relatively fixed.

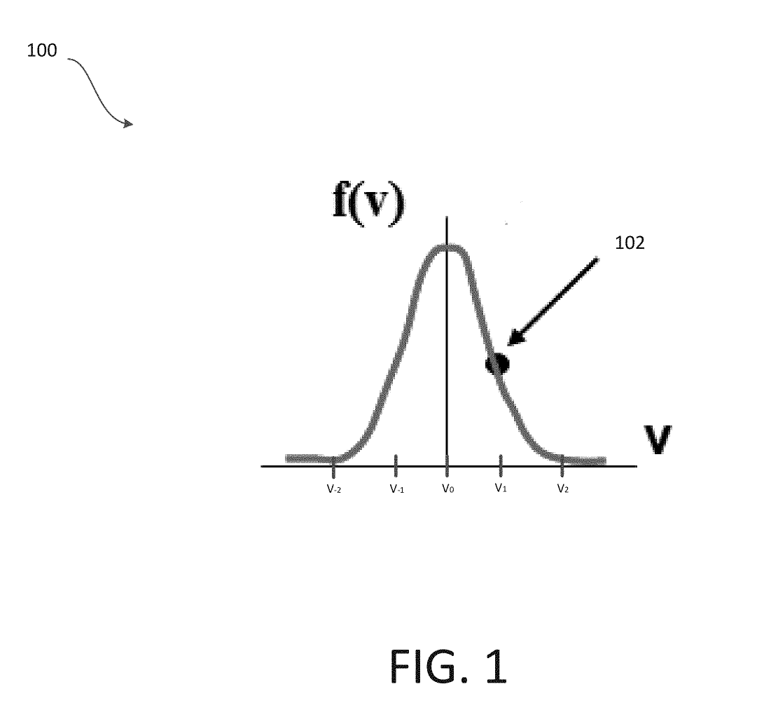

FIG. 1 illustrates a distribution function 100 of particles in a plasma. The horizontal axis of the distribution function 100 represents a particle velocity, including arbitrary velocity values v₋₂, v₋₁, v₀, v₁, and v₋₂. The vertical axis of the distribution function 100 represents a probability of a particle existing at a corresponding velocity. The particles are assumed to be in thermodynamic equilibrium, yielding a Maxwellian distribution function governed by Equation (1),

$$f ( v ) = {e}^{- \frac{{mv}^{2}}{2 {k}_{B} T}} \qquad ( 1 )$$

where m is a particle mass, v is a particle velocity, k_{B} is Boltzmann's constant, and T is a plasma temperature.

When an electromagnetic wave is provided to the plasma, the electromagnetic wave exchanges energy with the plasma particles with which the wave interacts. More specifically, the electromagnetic wave tends to lose energy to plasma particles moving more slowly than the wave, and gains energy from plasma particles moving more quickly than the wave. For example, consider an electromagnetic wave having a phase velocity of v₁ applied to the plasma. Per the probability distribution function 100 shown in FIG. 1, the point 102 corresponds to the probability of the plasma particles having the phase velocity v₁. As illustrated by FIG. 1, in this example, there is a higher probability that the electromagnetic wave encounter particles moving at velocities slower than v₁ than particles moving at velocities faster than v₁. In graphical terms, the area of the distribution function 100 to the left of v₁ is greater than the area of the distribution function 100 to the right of v₁. Thus, because in this example there are, on average, more plasma particles moving slower than the electromagnetic wave than there are plasma particles moving faster than the electromagnetic wave, the electromagnetic wave experiences a net decrease in energy. This is a phenomenon known as Landau damping, representative of the damping effect experienced by the wave.

An analogous phenomenon can be demonstrated in the case of a laser beam propagating through a non-linear optical medium, such as a non-linear crystal. The laser beam includes a plurality of “speckles” that are regions of high optical intensity in the beam caused by constructive interference. As discussed above, a plasma includes plasma ions and free plasma electrons that are small in comparison to the plasma ions. As discussed in more detail below, for the simulation and modeling purposes disclosed herein, the speckles in the laser beam can be considered analogous to the free plasma electrons, and the electrons of the non-linear crystal can be considered analogous to the plasma ions. The crystal electrons are large and static in comparison to the speckles in the same way that the plasma ions are large and static in comparison to the plasma free electrons.

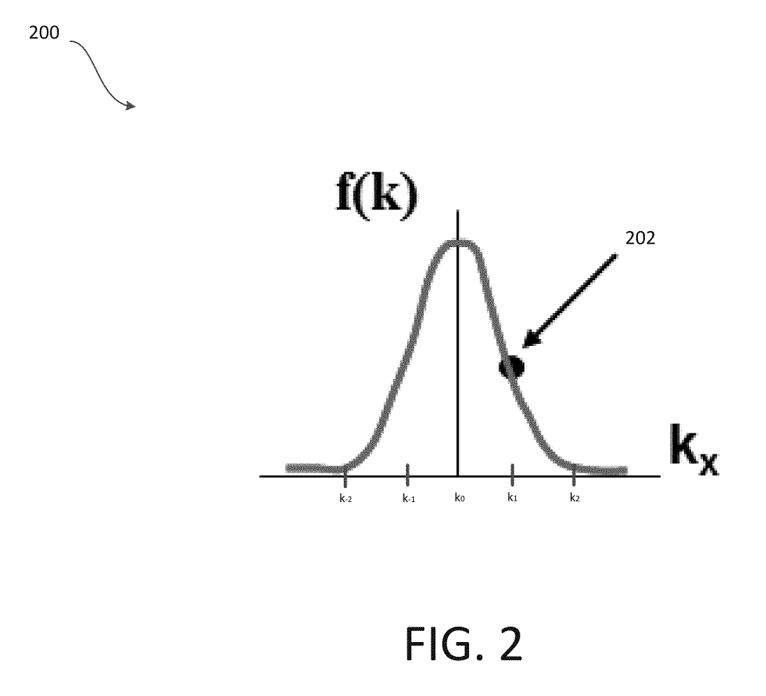

FIG. 2 illustrates a probability distribution function 200 of speckles in an optical beam such as a laser beam. The horizontal axis of the probability distribution function 200 represents an optical wavenumber, including arbitrary wavenumber values k₋₂, k₋₁, k₀, k₁, and k₋₂. The vertical axis of the distribution function 200 represents a probability of a speckle existing at a corresponding wavenumber. The speckles in the distribution function 200 are assumed to be in quasi-thermal equilibrium, yielding a Maxwellian distribution function governed by Equation (2),

$$f ( k ) = {e}^{- \frac{{k}_{x}^{2}}{Δ {k}^{2}}} \qquad ( 2 )$$

where k is a wavenumber, and x is an integer. In this example, point 202 corresponds to the probability of a speckle having a wavenumber k₁. Similar to the effects of Landau damping in a plasma system, in this example, the speckle at the wavenumber k₁ experiences a net decrease in energy as it propagates in the non-linear optical medium. As discussed in greater detail below, the similar Landau-like damping effect is related to partial wave incoherence as the speckles interact with the medium.

The similar damping effects observed with an electromagnetic wave in a plasma and a speckle in a crystal provides a so-called “physical interface” between the two systems. This interface between the systems allows physical properties of one of the systems to be mapped to respective physical properties of the other system. More specifically, as discussed above, speckles in a laser beam propagating through a non-linear crystal may be analogized to electrons in plasma, and electrons in the non-linear crystal may be analogized to positive ions in the plasma. Accordingly, where a laser beam is incident on the non-linear crystal, the distribution of the speckles in the incident beam may be compared to the distribution of speckles in the emergent beam to approximate a distribution of electrons and ions in an analogous plasma system. This relationship provides a mechanism for modeling the behavior of plasma in response to certain conditions.

Examples of the methods and systems discussed herein are not limited in application to the details of construction and the arrangement of components set forth in the following description or illustrated in the accompanying drawings. The methods and systems are capable of implementation in other embodiments and of being practiced or of being carried out in various ways. Examples of specific implementations are provided herein for illustrative purposes only and are not intended to be limiting. In particular, acts, components, elements and features discussed in connection with any one or more examples are not intended to be excluded from a similar role in any other examples.

Also, the phraseology and terminology used herein is for the purpose of description and should not be regarded as limiting. Any references to examples, embodiments, components, elements or acts of the systems and methods herein referred to in the singular may also embrace embodiments including a plurality, and any references in plural to any embodiment, component, element or act herein may also embrace embodiments including only a singularity. References in the singular or plural form are no intended to limit the presently disclosed systems or methods, their components, acts, or elements. The use herein of “including,” “comprising,” “having,” “containing,” “involving,” and variations thereof is meant to encompass the items listed thereafter and equivalents thereof as well as additional items. References to “or” may be construed as inclusive so that any terms described using “or” may indicate any of a single, more than one, and all of the described terms. In addition, in the event of inconsistent usages of terms between this document and documents incorporated herein by reference, the term usage in the incorporated features is supplementary to that of this document; for irreconcilable differences, the term usage in this document controls.

A mathematical relationship describing the physical interface between plasma systems and optical systems is discussed in greater detail. Equations (3)-(13) below describe a mathematical relationship between plasma systems and optical systems explaining the Landau-like speckle damping effect. Equations (14)-(18) expand on this fundamental mathematical relationship such that the relationship may be applied to higher dimensions and applied to practical plasma systems, as explained further below.

A fundamental set of coupled equations describing 3D optical wave propagation in a dispersive or diffractive medium can be expressed as,

$$\begin{matrix}i ( \frac{δ}{δ t} + {v}_{g} \cdot ∇ Ψ ) Ψ + \frac{β}{2} {∇}^{2} Ψ + n Ψ = 0 & ( 3 ) \\ {τ}_{m} \frac{δ n}{δ t} + n = κ G ( 〈 {Ψ}^{*} Ψ 〉 ) & ( 4 )\end{matrix}$$

where Ψ(r, t) is the slowly-varying complex amplitude as a function of the evolution dispersive variable t and the spatial dispersive variable r, v_{g} is the group velocity, ∇ is the nabla operator, β is the diffraction or second-order dispersion coefficient, κ is a non-linear coefficient, τₘ is the medium relaxation time, n(t, r) is the non-linear response function of the medium, and G(⋅) characterizes the non-linear properties of the medium, where bracket notation denotes the statistical ensemble average.

Assuming that the medium relaxation time τₘ is significantly longer than the characteristic time of the statistical wave intensity fluctuations τₛ, and is much less than the characteristic time scale of the wave amplitude variation τₚ (i.e., τₛ<<τₘ<<τₚ), Equations (3) and (4) may be reduced to,

$$i \frac{δ Ψ}{δ t} + \frac{β}{2} {∇}^{2} Ψ + κ G ( 〈 {Ψ}^{*} Ψ 〉 ) Ψ = 0 \qquad ( 5 )$$

where the coordinate system of Equation (5) has been transformed to the reference system moving with the phase velocity v_{g}.

Equation (5) may be transformed between phase space and Hilbert space using the Wigner transform, which is used to describe the dynamics of a quantum state of a system in classical space language. The Wigner transform (including the Klimontovich statistical average) may be expressed as,

$$ρ ( p , r , t ) = \frac{1}{{( 2 Π )}^{3}} {\int }_{- ∞}^{∞} {d}^{3} ξ {e}^{i p \cdot ξ} 〈 {Ψ}^{*} ( r + \frac{ξ}{2} , t ) Ψ ( r - \frac{ξ}{2} , t ) 〉 \qquad ( 6 )$$

where ρ(p, r, t) represents the Wigner coherence function. The Wigner coherence function is a particle density function describing system points' momentum p and position r, with respect to time t. Equation (6) may be applied to Equations (3) and (4) to yield,

$$\frac{δ ρ}{δ t} + β p \cdot \frac{δ ρ}{δ r} + κ \frac{δ G ( 〈 {\vert Ψ \vert}^{2} 〉 )}{δ r} \cdot \frac{δ ρ}{δ p} = 0 \qquad ( 7 )$$

Equation (7) implies the conservation of the number of optical quasiparticles (i.e., speckles) in phase space. Using Liouville's theorem, which asserts that the phase space distribution function is constant along the system trajectory, Hamilton's equations of motion may be derived as,

$$\begin{matrix}ω = \frac{β}{2} {p}^{2} - κ G ( 〈 {Ψ}^{*} Ψ 〉 ) & ( 8 ) \\ \dot{r} = \frac{δ ω}{δ p} = β p & ( 9 ) \\ \dot{p} = - \frac{δ ω}{δ r} = κ \frac{δ G ( 〈 {Ψ}^{*} Ψ 〉 )}{δ r} & ( 10 )\end{matrix}$$

where ω is the Hamiltonian and, where Equations (8)-(10) are representative of quasiparticles moving in phase space, β is the mass of the quasiparticle, κ is the charge of the quasiparticle, and G is the electric potential.

In the context of an optical system, Equations (8)-(10) may be indicative of parameters of speckles as quasiparticles. For example, consider the Modulational Instability (MI) of a one-dimensional (1D) plane wave with a constant amplitude in a non-linear Kerr-like medium, for which G ( [symbol] Ψ*Ψ [symbol] )= [symbol] |Ψ|² [symbol] . For coherent light, a perturbation thereof leads to an instability having a growth rate of,

$$Ω = i \frac{β κ}{2} {( \frac{4 {κΨ}_{0}^{2}}{β {κ}^{2}} - 1 )}^{1 / 2} \qquad ( 11 )$$

To analyze the effects of the incoherence, a Wigner distribution function may be assumed having the form ρ(p, t, x)=ρ₀(p)+ρ₁ exp[i(Kx−Ωt)], where ρ₀»|ρ₁|. Expanding on the linear evolution of the perturbation ρ₁, the following dispersion relation may be obtained,

$$1 + \frac{κ}{β} {\int }_{- ∞}^{+ ∞} \frac{{ρ}_{0} ( p + \frac{K}{2} ) - {ρ}_{0} ( p - \frac{K}{2} )}{K ( p - \frac{Ω}{β K } )} d p = 0 \qquad ( 12 )$$

Applying the linearized Vlasov relation discussed above with respect to Equation (7) to Equation (12) yields,

$$1 + \frac{κ}{β} {\int }_{- ∞}^{+ ∞} \frac{d {ρ}_{0} / d ρ}{( p - \frac{Ω}{β K } )} d p = 0 \qquad ( 13 )$$

Equation (13) offers significant insight into an optical-plasma interface. Although Equation (13) includes optical parameters, the mathematical relationship is similar to the dispersion relation for electron plasma wave. As discussed above, electron plasma waves are well-known to exhibit the effects of Landau damping. Similarly, the kinetic integrals of Equations (12) and (13) can be represented as the sum of a principal value and a residue contribution, where the residue contribution leads to a Landau-like damping of the perturbation.

The stabilizing Landau-like damping effect is not representative of ordinary dissipative damping. Conversely, the Landau-like damping effect is an energy-conserving self-action effect within a partially incoherent wave, which causes a redistribution of the Wigner spectrum because of the interaction between different parts of the spectrum. The spectral redistribution counteracts the MI, similar to the nonlinear propagation of electron plasma waves interacting with intense electromagnetic radiation.

As discussed above, observation of Landau-like damping effects in optical systems offers insight into an interface between optical and plasma systems. This bridge is further expanded by the observation of two-stream (or “bump-on-tail”) instability effects in optical systems. Two-stream instability is a well-known instability phenomenon in plasma systems, which is caused by the injection of a stream of electrons into a plasma. The injection of the stream of electrons causes plasma wave excitation in a phenomenon that is, conceptually, the inverse of Landau damping. Whereas in the case of Landau damping the existence of a greater number of particles that move slower than the wave phase velocity leads to an energy transfer from the wave to the particles, in the case of two-stream instability, the velocity distribution of an injected stream of electrons has a “bump” on its “tail.” If a wave has phase velocity in the region where the slope is positive, there is a greater number of faster particles than slower particles, and so there is a greater amount of energy being transferred from the fast particles to the wave, leading to exponential wave growth.

Similar effects may be observed in an optical system as a result of the dynamic coupling of two partially-coherent optical beams in a self-focusing photorefractive medium. Using wave-kinetic theory, the two-stream dynamics are interpreted as the resonant interaction of light speckles with interaction waves, similar to the interaction of a plasma with an injected stream of electrons.

The physical interface discussed above enables certain plasma system properties to be mapped to corresponding optical system properties. More specifically, according to certain embodiments, plasma quantum properties can be mapped to optical quantum properties, as discussed further below.

Electron density in a plasma system is subject to plasma oscillations. Quantization of the plasma oscillation yields a quasiparticle known in the art as a plasmon, which reflects electron behavior in the plasma. Properties of the plasmons may be determined using Equations (8)-(10), where β is the mass of the plasmon, κ is the charge of the plasmon, and G is the electric potential applied to the plasmon.

Properties of quasiparticles in optical systems may also be determined using Equations (8)-(10). As discussed above, lasers include packets of photons referred to as speckles, which may be analogously modelled as quasiparticles. For example, it may be desirable to determine one or more properties of a plasmon in a plasma system. Rather than directly computing properties of the plasmon, Equations (8)-(10) may be executed with respect to a speckle in an optical system and mapped to corresponding properties of the plasmon. This provides a less expensive and more convenient way to model plasmas.

Accordingly, Equations (8)-(10) provide a mathematical relationship mapping speckles and electrons in an optical system to electrons and ions in a plasma system, respectively. However, in the context of an optical system using a laser source, the foregoing equations are applied to coherent light in which dispersion effects and transverse spreading effects are neglected. The optical system is therefore restricted inasmuch as the laser beam travels in only a single direction (the propagation direction z) without evolving in the transverse directions.

According to certain embodiments, there is provided a mechanism by which plasma evolution can be modeled in all six dimensions of phase space. With respect to the propagation direction z in an optical system, the time dimension is inherently linked to the propagation direction inasmuch as the optical wave propagates at a known speed. Accordingly, the time dimension t may be used to permit the spatial dimension z to be considered by substituting the time dimension tin Equation (3) with the propagation direction z.

With respect to the transverse directions r, β in Equation (3) represents either a diffraction or second order dispersion coefficient. If both dispersion (i.e., spreading in time) and diffraction (i.e., r-dimensional or transverse spreading) are simultaneously considered, then all plasma space dimensions may be considered. Applying the foregoing principles, the optical non-linear Schrodinger equation may be written as,

$$\begin{matrix}i \frac{δ Ψ}{δ z} = - \frac{1}{2 {k}_{0}} {∇}^{2} Ψ + \frac{{β}_{2}}{2} \frac{{δ}^{2} Ψ}{δ {T}^{2}} - {k}_{0} {n}_{2} {\vert Ψ \vert}^{2} Ψ & ( 14 ) \\ {β}_{2} = \frac{δ}{δ ω} \frac{1}{{v}_{g}} = \frac{{δ}^{2} k}{δ {ω}^{2}} = \frac{2}{c} ( \frac{δ n}{δ ω} ) + \frac{{ω}_{0}}{c} ( \frac{{δ}^{2} n}{δ {ω}^{2}} ) & ( 15 )\end{matrix}$$

where Ψ(x, y, z, t) is the complex amplitude, β₂ is the Group Velocity Distribution (GVD) coefficient describing the dispersion of the wave, k₀ is the central wave number of the wave packet, n₂ is a Kerr type non-linearity coefficient, z is the propagation direction, ∇² is the second derivative in the transverse directions, and T is the time coordinate adjusted for a moving frame.

Equations (14)-(15) describe how light evolves in 3D space and time as it interacts with a dispersive medium, whereas dispersive effects had previously been ignored. If the time coordinate T is rescaled as,

$$τ = \frac{T}{\sqrt{- {β}_{2} {k}_{0}}} \qquad ( 16 )$$

then Equation (14) may be simplified as,

$$i \frac{δ Ψ }{δ z} = - \frac{1}{2 {k}_{0}} ( \frac{{δ}^{2}}{δ {x}^{2}} + \frac{{δ}^{2}}{δ {y}^{2}} + \frac{{δ}^{2}}{δ {τ}^{2}} ) Ψ - {k}_{0} {n}_{2} {\vert Ψ \vert}^{2} Ψ \qquad ( 17 )$$

Applying the Wigner transform discussed above with respect to Equation (6) to Equation (17) yields an equation similar to the Vlasov-Poisson equation, Equation (7), but expressed in six phase space dimensions,

$$\frac{δ ρ}{δ t} + \frac{1}{{k}_{0}} p \cdot \frac{δ ρ}{δ r} + {n}_{2} \frac{δ G ( 〈 {\vert Ψ \vert}^{2} 〉 )}{δ r} \cdot \frac{δ ρ}{δ p} = 0 \qquad ( 18 )$$

Equation (18) may therefore be used to determine the speckle distribution function ρ which, in turn, may be mapped to the plasma distribution function. In practice, the speckle distribution function ρ may be extrapolated from measured phase and amplitude information, for example. The rescaled time coordinate τ acts as a third spatial dimension, allowing all six dimensions to be explored. Conversely, the propagation direction z in which the electromagnetic wave propagates takes the role of time.

A critical assumption of Equation (16), however, is that the GVD coefficient β₂ of the medium interacting with the electromagnetic wave is negative, because the rescaled time coordinate τ, the time coordinate T, and the central wave number k₀ are each real, non-negative values.

A negative GVD coefficient β₂ is indicative of a material exhibiting anomalous dispersion. A dispersive medium has an index of refraction which varies as a function of the frequency of electromagnetic radiation passing through the medium. In a normal dispersive medium, the refractive index of the media decreases with respect to frequency. In an anomalous dispersive medium, by contrast, the refractive index of the medium increases with respect to frequency.

A negative GVD coefficient may be obtained in one of several ways. For example, certain materials exhibit a negative GVD in response to electromagnetic waves at wavelengths above a zero-dispersion wavelength, and a positive GVD in response to electromagnetic waves at wavelengths below the zero-dispersion wavelength. Silica is one such material, having a zero-dispersion wavelength of approximately 1300 nm. Accordingly, if an electromagnetic wave having a wavelength above approximately 1300 nm is applied to silica, the electromagnetic wave is subject to a negative GVD.

In another example, meta-materials having negative refractive indices may be utilized to obtain a negative GVD coefficient. Metamaterials are specially-engineered structures that employ alternating variations of material properties, such as the relative electrical permittivity and relative magnetic permeability, in one, two, or three dimensions on a scale much smaller than the wavelength of the wave interacting with the structure. The materials may be structured and arranged such that the materials exhibit a negative GVD coefficient.

In still other examples, a pair of prisms or a pair of diffraction gratings may be used. The relative alignment of the prisms or the gratings may be adjusted to control a negative GVD coefficient, even where the prisms or gratings individually have positive GVD coefficients. For example, adjustment of the alignment of a pair of prisms to modulate a negative GVD coefficient using refraction is discussed in “Negative Group-Velocity Dispersion Using Refraction,” O. E. Martinez, J. P. Gordon, and R. L. Fork, J. Opt. Soc. Am. A 1, 1003-1006 (1984).

In another example, certain crystals may be used in combination with a pump beam generated by a pump beam generator. The pump beam is generally configured to modify the electron structure of the crystal to generate a spectral antihole, which may be used to obtain a negative GVD coefficient. One example of a crystal in which a spectral antihole may be observed is an alexandrite crystal exhibiting a spectral antihole around 476 nm, as discussed in greater detail below in “Superliminal and Slow Light Propagation in a Room-Temperature Solid,” Matthew S. Bigelow, Nick N. Lepeshkin, Robert W. Boyd, Science Vol. 301, Issue 5630, pp. 200-402 (2003).

In another example, a graded-index (GRIN) lens may be used. Whereas pairs of prisms may only achieve a limited range of negative GVD coefficients, and pairs of diffraction gratings may experience high loss, GRIN lenses allow modulation of the GVD coefficient across a wide range of values and with low loss. The GVD coefficient may be modulated by tuning a beam offset relative to the optical axis of the GRIN lens. Modulation of a GVD coefficient using GRIN lenses is discussed in greater detail in “Adjustable Negative Group-Velocity Dispersion in Graded-Index Lenses,” A. Tien, R. Chang, and J. Wang, Optics Letters Vol. 17, No. 17 (1992).

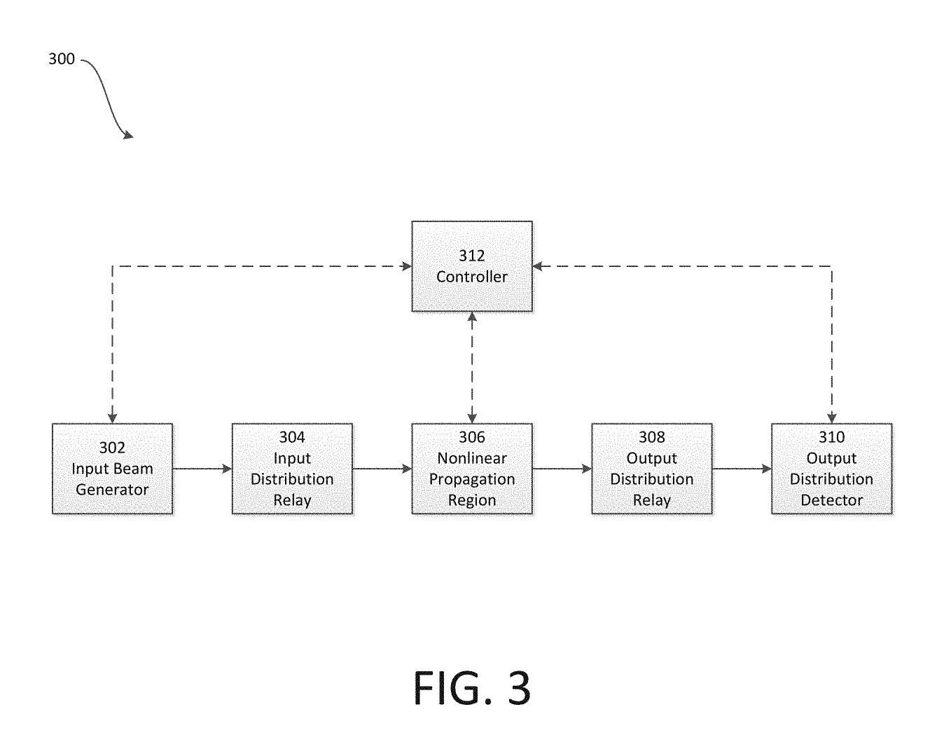

FIG. 3 illustrates an optical system 300 according to one embodiment. The optical system 300 is capable of modelling plasma dynamics by selecting parameters of an input laser beam, providing the laser beam to a medium exhibiting a negative GVD coefficient, and detecting parameters of an output laser beam.

A change in the parameters of the laser beam after interacting with the medium is subsequently analyzed to determine a change in a speckle distribution function. The results of the analysis are used to model an analogous change in dynamic plasma distribution parameters, where laser beam speckles are analogous to electrons in plasma and the electrons of the medium are analogous to ions in plasma.

Referring to FIG. 3, the optical system 300 includes an input beam generator 302, an input distribution relay 304, a nonlinear propagation region 306, an output distribution relay 308, an output distribution detector 310, and a controller 312.

The input beam generator 302 is coupled to the input distribution relay 304 at an output, and is configured to be coupled to the controller 312. The input distribution relay 304 is coupled to the input beam generator 302 at an input, and the nonlinear propagation region 306 at an output. The nonlinear propagation region 306 is coupled to the input distribution relay 304 at an input and the output distribution relay 308 at an output, and is configured to be coupled to the controller 312.

The output distribution relay 308 is coupled to the nonlinear propagation region 306 at an input, and the output distribution detector 310 at an output. The output distribution detector 310 is coupled to the output distribution relay 308 at an input, and is configured to be coupled to the controller 312. The controller 312 is configured to be coupled to the input beam generator 302, the nonlinear propagation region 306, and the output distribution detector 310.

The input beam generator 302 is generally configured to generate an input laser beam with parameters specified according to one or more control signals received from the controller 312. In alternate embodiments, the input beam generator 302 may select the parameters itself, and communicate one or more signals to the controller 312 notifying the controller 312 of the parameter selection.

The parameters may be indicative of a speckle distribution in the laser beam, analogous to free electron distribution in a plasma. The initial parameters of the input laser beam can be specified by the controller 312 to represent an initial distribution of electrons in a plasma system, for example. The input beam generator 302 generates the laser beam according to the received control signal(s), or according to a parameter selection made by the input beam generator 302, and provides the input laser beam to the input distribution 304 subsequent to generating the beam.

The input distribution relay 304 is generally configured to receive the input laser beam from the input beam generator 302, adjust the width and direction of the input laser beam, and provide the adjusted laser beam to the nonlinear propagation region 306. For example, the input distribution relay 304 may include a refractive lens configured to collect the laser beam and adjust the laser beam to a desired width. The function of the input distribution relay 304 is to ensure that the input laser beam is incident on the nonlinear propagation region 306 at an intended width and position.

The nonlinear propagation region 306 is generally configured to receive the adjusted laser beam from the input distribution relay 304, modulate the parameters laser beam, and provide the modulated laser beam to the output distribution relay 308. In some examples, the nonlinear propagation region 306 may include a material having a tunable negative GVD coefficient as discussed above. The electron structure of the nonlinear propagation region 306 modulates the parameters of the laser beam analogously to the modulation of the free electron distribution in a plasma by the plasma ions.

Properties of the nonlinear propagation region 306, such as the electron structure of the nonlinear propagation region 306, may be modulated in response to one or more control signals received from the controller 312. Changes to the properties of the nonlinear propagation region 306 correspondingly affect the modulation of the parameters of the laser beam interacting with the nonlinear propagation region 306. The nonlinear propagation region 306 provides the modulated laser beam to the output distribution relay 308.

The output distribution relay 308 is generally configured to receive the modulated laser beam from the nonlinear propagation region 306, adjust the width and direction of the modulated laser beam, and provide the adjusted laser beam to the output distribution detector 310. Similar to the input distribution relay 304, the output distribution relay 308 may include a refractive lens configured to provide the laser beam to the output distribution detector 310 at an intended width and position.

The output distribution detector 310 is generally configured to receive the adjusted laser beam from the output distribution relay 308 and detect the parameters of the adjusted laser beam. For example, the output distribution detector 310 may include a volume hologram configured to detect at least one of the phase and amplitude of the laser beam received from the output distribution relay 308.

In other embodiments, the output distribution detector 310 may employ linear tomography to detect parameters of the adjusted laser beam. In still other embodiments, any other known techniques for detecting desired parameters of electromagnetic radiation may be employed. The output distribution detector 310 communicates the detected parameters to the controller 312.

The controller 312 is generally configured to perform at least two functions. First, the controller 312 is configured to analyze changes in laser beam parameters resulting from interaction with the linear propagation region 306. In some examples, analysis includes specifying input parameters to the input beam generator 302, receiving output parameter measurements from the output distribution detector 310, and detecting a change between the laser beam parameters. The analyzed changes may be representative of changes in the speckle distribution function of the laser beam after interaction with the medium, which may be used to model changes in a plasma distribution as discussed above.

Second, the controller 312 is configured to adjust system parameters of the optical system 300. For example, the controller 312 may communicate one or more signals to the input beam generator 302 to adjust parameters of the input laser beam, or may communicate one or more signals to the nonlinear propagation region 306 to adjust parameters of the nonlinear propagation region 306. These adjustments may be analogous to adjustments in plasma free electron distribution and ion distribution, respectively.

Adjusting parameters of the nonlinear propagation region 306 varies depending on the embodiment of the nonlinear propagation region 306. For example, as discussed above, the nonlinear propagation region 306 may include a pair of diffraction gratings. By adjusting the pair of diffraction gratings, the index of refraction of the nonlinear propagation region 306 may be modulated. Modulation of the index of refraction, in turn, modulates the group velocity of electromagnetic radiation interacting with the nonlinear propagation region 306.

Similarly, where the nonlinear propagation region 306 includes a pair of prisms, the alignment of the prisms may be adjusted to modulate the index of refraction and, correspondingly, the group velocity of electromagnetic radiation interacting with the nonlinear propagation region 306. As will be appreciated in light of the foregoing discussion, and particularly Equation (15), modulation of the group velocity correspondingly modulates the GVD coefficient. Accordingly, where the nonlinear propagation region 306 includes a pair of prisms or a pair of diffraction gratings, the controller 312 may adjust the GVD coefficient of the nonlinear propagation region 306 by altering the alignment of the prisms or diffraction gratings.

Alternatively, where the nonlinear propagation region 306 includes certain crystals, the crystal structure may be modulated by a pump beam generated by a pump beam generator included in, or optically coupled to, the nonlinear propagation region 306. More specifically, the pump beam is configured to excite electrons in the crystal to modulate the electron structure of the crystal, as discussed in greater detail below. Accordingly, where the nonlinear propagation region 306 includes crystals in combination with a pump beam, the controller 312 may modulate the output of the pump beam generator to control the electron structure of the nonlinear propagation region 306.

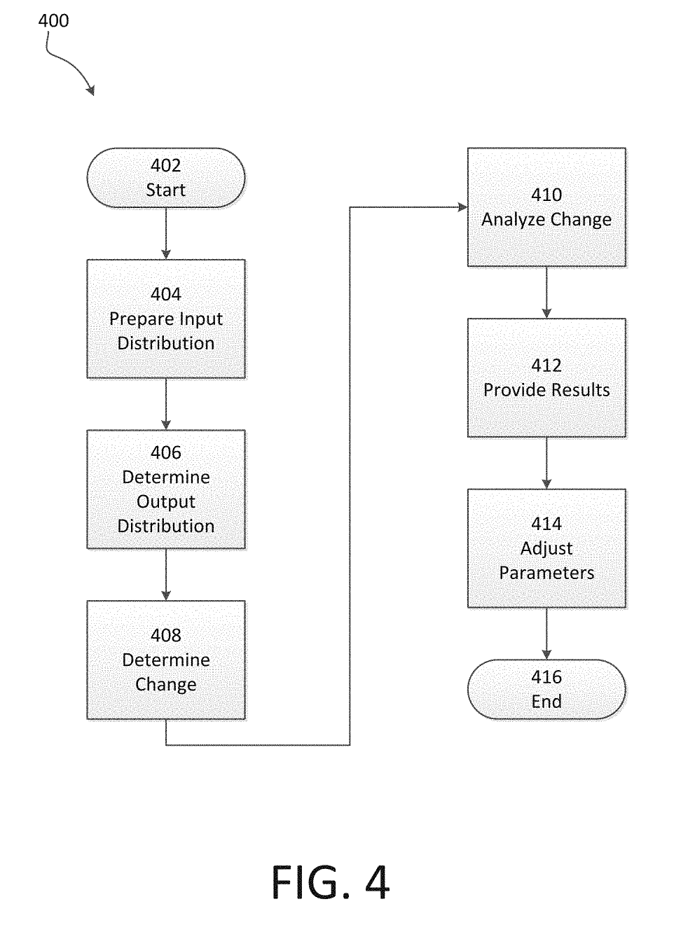

FIG. 4 illustrates a method 400 of operating an optical system, such as the optical system 300. In some embodiments, the method 400 may be executed by a controller, such as the controller 312.

At act 402, the process 400 begins. At act 404, an input distribution of an input laser beam is prepared by selecting one or more values of one or more beam parameters to provide to a beam generator. For example, with reference to FIG. 3, act 404 may include calculating phase and amplitude values for an input laser beam to provide to the input beam generator 302 where the phase and amplitude are representative of a speckle distribution function. The initial phase and amplitude values of the laser beam may be selected to model an initial distribution of electrons and ions in a plasma, for example. Alternatively, the controller may receive one or more values of the one or more parameters from the beam generator.

At act 406, the controller determines parameters of the laser beam output. For example, act 406 may include receiving one or more signals from an output detector, such as the output distribution detector 310, indicative of the parameters such as phase and amplitude. At act 408, the controller determines a change in the laser beam parameters. For example, act 408 may include determining a difference in the phase and amplitude detected at act 406 relative to the phase and amplitude selected at act 404.

At act 410, the controller analyzes the change determined at act 408. More specifically, act 410 may include correlating the change in the laser beam parameters to a modelled change in analogous plasma parameters. For example, where the change in the laser beam parameters is indicative of a change in a speckle distribution function of the laser beam, the change in the speckle distribution function may be used to model a change in an particle distribution in an analogous plasma system. It is to be appreciated that, in executing act 410, the controller may be utilizing one or more of the mathematical relationships derived above with respect to Equations (14)-(18), such as by utilizing phase and amplitude information to determine a speckle distribution function ρ.

At act 412, the controller provides the results of the analysis at act 410 to an output. For example, the controller may provide the results to a user display. In other embodiments, the controller may store the results of the analysis in a local or remote storage in addition to, or in lieu of, providing the results to the user display.

At act 414, the controller adjusts system parameters responsive to a user input and/or responsive to a determination made by the controller. For example, the controller may communicate one or more control signals to the input beam generator 302 to change the input distribution of the beam. Changing the input distribution of the beam may include controlling the input beam generator 302 to generate a laser beam with a different phase or amplitude as compared to a phase or amplitude of a beam previously generated at act 402.

Alternatively, the controller may communicate one or more control signals to the nonlinear propagation region 306 to alter parameters of the nonlinear propagation region 306. For example, the controller may alter an alignment of a pair of diffraction gratings or a pair of prisms, or may alter a pump beam provided to the nonlinear propagation region 306. Altering the pump beam may include communicating one or more control signals to a pump beam generator. At act 216, the process 400 ends.

It is therefore to be appreciated that systems and methods been provided to model a distribution of particles in a plasma system using optical parameters. A relationship between properties of a plasma system and properties of an optical system is described above with respect to Equations (1)-(18). A controller, such as the controller 312, may be implemented to detect one or more parameters of the optical system, and model corresponding parameters in a plasma system.

In some examples, the controller 312 can include one or more processors or other types of controllers. The controller 312 may perform a portion of the functions discussed herein on a processor, and perform another portion using an Application-Specific Integrated Circuit (ASIC) tailored to perform particular operations. Examples in accordance with the present invention may perform the operations described herein using many specific combinations of hardware and software and the invention is not limited to any particular combination of hardware and software components. The controller 312 may include, or may be communicatively coupled to, a non-transitory computer-readable medium configured to store instructions which, when executed by the controller 312, cause the controller 312 to execute one or more acts discussed above with respect to FIG. 4.

In some embodiments, the controller 312 may be coupled to a display, a storage element, and one or more input/output modules. For example, the controller 312 may communicate results of the analysis of the optical system 300 to the display responsive to commands received from a user via the input/output modules, such that a user may view the results of the analysis. The controller 312 may also or alternatively store the results of the analysis in the storage element for subsequent retrieval.

As discussed above with respect to the nonlinear propagation region 106, a pump beam may be implemented in combination with certain crystals in which antiholes may be observed. More specifically, the pump beam is provided to the crystal to excite ground-state electrons in the crystal to an excited state. Electrons quickly decay from the excited state to a metastable state, and finally back to the ground state after a relatively long relaxation time T₁.

A second beam, referred to as a probe beam, is provided to the crystal and causes the electrons to oscillate between the ground and metastable states at a beat frequency δ between the pump beam and probe beam. Because the relaxation time T₁ is relatively long, however, the oscillations between the pump beam and probe beam will only occur with a significant amplitude if the beat frequency δ is so small that δT₁ is approximately 1.

When this condition is met, the pump beam can scatter the temporarily-modulated ground state electrons off into the probe beam, resulting in reduced absorption of the probe wave. Because the probe beam experiences the reduced absorption over a very narrow frequency range (i.e., roughly 1/T₁), the index of refraction of the crystal increases very rapidly over the frequency range.

Rapid changes in an index of refraction as a result of the absorption feature is a well-known phenomenon described by the Kramers-Kronig relations, as will be appreciated by one of ordinary skill in the art. The group velocity of the beam correspondingly changes at a very rapid rate. This narrow region of reduced absorption, referred to generally as a spectral hole, leads to a phenomenon known as slow light.

In contrast, a narrow region of increased absorption, referred to generally as a spectral antihole, leads to fast light. This is a result of the index of refraction decreasing rapidly with frequency in the narrow region of increased absorption, which leads to a negative GVD coefficient. In an alexandrite crystal, an antihole can be observed around approximately 457 nm. The spectral behavior of the alexandrite crystal is discussed in greater detail in “Superliminal and Slow Light Propagation in a Room-Temperature Solid,” Matthew S. Bigelow, Nick N. Lepeshkin, Robert W. Boyd, Science Vol. 301, Issue 5630, pp. 200-402 (2003).

Although the foregoing discussion has described the usage of laser beams, it is to be appreciated that any form of electromagnetic radiation may be implemented in alternate embodiments. For example, although the input beam generator 302 is described as generating a laser beam, in alternate embodiments the input beam generator 302 may generate any form of non-ionizing electromagnetic radiation.

Furthermore, although the foregoing discussion has been directed to utilization of an optical system to model plasma behavior, in alternate embodiments the optical system may model other behavior. For example, as discussed above with respect to Equations (12) and (13), the Wigner spectral redistribution counteracts the MI similar to the nonlinear propagation of electron plasma waves interacting with intense electromagnetic radiation. This counteraction is also similar to nonlinear interaction between random phase photons and sound waves in electron-positron plasma, and the longitudinal dynamics of charged-particle beams in accelerators. Similar principles may also be applied to model other differential equations such as fluid and atmospheric dynamics.

Thus, an optical modelling solution has been described. The optical model may be utilized to simulate effects in analogous systems which would otherwise be extremely computationally-burdensome to compute. For example, the optical model may be used to model a distribution of electrons and ions in plasma at a significantly-reduced computational cost.

Having thus described several aspects of at least one embodiment, it is to be appreciated that various alterations, modifications, and improvements will readily occur to those skilled in the art. Such alterations, modifications, and improvements are intended to be part of this disclosure and are intended to be within the scope of the invention. Accordingly, the foregoing description and drawings are by way of example only, and the scope of the invention should be determined from proper construction of the appended claims, and their equivalents.

What is claimed is:

1. An optical system for modeling a distribution of plasma particles, the system comprising:
an electromagnetic wave generator configured to generate an electromagnetic wave having a first set of values of at least one parameter;
a non-linear medium configured to receive, from the electromagnetic wave generator, the electromagnetic wave;
an output detector configured to detect a second set of values of the at least one parameter responsive to propagation of the electromagnetic wave through the non-linear medium; and
a controller configured to select the first set of values of the at least one parameter, communicate the first set of values of the at least one parameter to the electromagnetic wave generator, receive, from the output detector, the second set of values of the at least one parameter, and determine, based on the first set of values of the at least one parameter and the second set of values of the at least one parameter, a distribution of plasma particles.

2. The system of claim 1, wherein the at least one parameter includes at least one of a phase of the electromagnetic wave and an amplitude of the electromagnetic wave.

3. The system of claim 1, wherein the at least one parameter is indicative of a speckle distribution function of the electromagnetic wave.

4. The system of claim 1, wherein the non-linear medium has a negative group velocity distribution coefficient.

5. The system of claim 4, wherein the controller is further configured to modulate a value of the negative group velocity distribution coefficient of the non-linear medium.

6. The system of claim 1, wherein the non-linear medium includes a pair of diffraction gratings.

7. The system of claim 1, wherein the non-linear medium includes a pair of prisms.

8. The system of claim 1, wherein the non-linear medium includes at least one graded-index lens.

9. The system of claim 1, wherein the non-linear medium includes one or more metamaterials.

10. The system of claim 1, further comprising a pump beam generator configured to provide a pump beam to the non-linear medium.

11. The system of claim 10, wherein providing the pump beam to the medium modifies the electron structure of the non-linear medium.

12. The system of claim 1, wherein the output detector includes a volume hologram.

13. The system of claim 1, wherein the output detector is configured to detect the second set of values of the at least one parameter using linear tomography.

14. A method of modeling a distribution of plasma particles, the method comprising:
selecting a first set of values of one or more parameters of an electromagnetic wave;
communicating the one or more parameters to an electromagnetic wave generator;
detecting a second set of values for the one or more parameters of the electromagnetic wave;
analyzing the first set of values of the one or more parameters and the second set of values of the one or more parameters; and
determining, based on the analysis, a distribution of particles in a plasma system.

15. The method of claim 14, wherein the one or more parameters include at least one of a phase of the electromagnetic wave and an amplitude of the electromagnetic wave.

16. The method of claim 14, wherein the one or more parameters are indicative of a speckle distribution function of the electromagnetic wave.

17. The method of claim 14, further comprising modulating a group velocity distribution coefficient of a medium interacting with the electromagnetic wave.

18. A non-transitory computer-readable medium storing sequences of computer-executable instructions for modeling a distribution of plasma particles, the sequences of computer-executable instructions including instructions that instruct at least one processor to:
select a first set of values of one or more parameters of an electromagnetic wave;
communicate the one or more parameters to an electromagnetic wave generator;
detect a second set of values for the one or more parameters of the electromagnetic wave;
analyze the first set of values of the one or more parameters and the second set of values of the one or more parameters; and
determine, based on the analysis, a distribution of particles in a plasma system.

19. The computer-readable medium of claim 18, wherein the one or more parameters include at least one of a phase of the electromagnetic wave and an amplitude of the electromagnetic wave.

20. The computer-readable medium of claim 18, wherein the sequences of computer-executable instructions further include instructions that instruct the at least one processor to modulate a group velocity distribution coefficient of a medium interacting with the electromagnetic wave.
